(19) United States
(12) Patent Application Publication
(10) Pub. No.: US 2007/0279071 A1
(43) Pub. Date: Dec. 6, 2007

(54) Method and System for Diagnosing Degradation in Vehicle Wiring

(76) Inventor: Harry E. Orton, North Vancouver (CA)

Correspondence Address: OYEN, WIGGS, GREEN & MUTALA LLP;480 - THE STATION, 601 WEST CORDOVA STREET, VANCOUVER, BC, V6B 1G1, CA

(21) Appl. No.: 10/576,571

(22) PCT Filed: Oct. 20, 2003
(86) PCT No.: PCT/CA03/01603

§ 371 Date: May 7, 2007

(51) Int. Cl. G01R 31/02; G01R 31/00

(52) U.S. Cl. 324/523; 324/539; 340/438

(57) ABSTRACT

The invention provides a system for diagnosing degradation of a plurality of wires in an electrical system having plurality of loads connected by the plurality of wires to a direct current power source, the plurality of wires arranged into a bundle near the power source. The system comprises a current sensor located proximate to the bundle for producing a signal representative of a current in the bundle, a signal processor coupled to the sensor to receive the signal from the current sensor, a pattern database coupled to the signal processor to provide the signal processor with expected patterns of currents drawn by the plurality of loads and patterns of arcs which may occur in the plurality of wires, and, an output device coupled to the signal processor to receive an indication of a location at which an arc occurred in the plurality of wires.

### TECHNICAL FIELD

The invention relates to methods and systems for diagnosing degradation in a wiring system of a vehicle, and more particularly, to methods and systems for monitoring a wiring system for arcs.

### BACKGROUND

Mobile vehicles such as cars, trucks, trains and ships generally have electrical systems with a power source such as a 12 or 42 volt battery. FIG. 1 schematically illustrates a prior art example of such an electrical system 10. Electrical system 10 comprises a plurality of loads 12 connected to a power source 14. Loads 12 are supplied with dc current from power source by means of a plurality of wires 16. Wires 16 are gathered into a bundle 18 near power source 14.

The wires of a vehicle's electrical system are typically insulated with PTFE (polytetrafluoro-ethylene) or polyimide, sometimes referred to by the trade names Hypolon™ or Mylar™ insulation (not shown). PTFE offers high temperature resistance, high dielectric strength, fluid resistance and low smoke generation. Its weaknesses include susceptibility to cold flow and low dynamic cut-through resistance. Polyimide has all of the properties of PTFE, but has improved resistance to dynamic cut-through. Unfortunately polyimide has been found to be susceptible to arc propagation and degradation due to hydrolysis.

Various factors can lead to premature degradation of the insulation resulting in the deterioration of the electrical and physical properties of the insulating material and to eventual failure of the wires. These factors can include loss of plasticizer with time and temperature, hydrolysis, cold flow, filamentary alignment of the insulation fibres making any insulation tapes susceptible to cracking, unravelling of taped insulation with age, and loss of dielectric, chemical and mechanical properties due to temperature cycling and high temperature operation. Deterioration of the insulation mechanical properties can be so extensive that cracking and opening of the insulation material can occur.

The wires are usually gathered into smaller bundles which are routed through the vehicle to deliver power to the loads. These smaller bundles can be enclosed within the structure of the vehicle in order to minimize their obtrusiveness. This makes it difficult to test the wires for degradation of their insulation.

There exists a need for efficient methods and systems for diagnosing degradation in the wiring of electrical systems in vehicles.

### SUMMARY OF THE INVENTION

The invention provides a system for diagnosing degradation of a plurality of wires in an electrical system having plurality of loads connected by the plurality of wires to a direct current power source, the plurality of wires arranged into a bundle near the power source. The system comprises a current sensor located proximate to the bundle for producing a signal representative of a current in the bundle, a signal processor coupled to the sensor to receive the signal from the current sensor, a pattern database coupled to the signal processor to provide the signal processor with expected patterns of currents drawn by the plurality of loads and patterns of arcs which may occur in the plurality of wires, and, an output device coupled to the signal processor to receive an indication of a location at which an arc occurred in the plurality of wires.

The current sensor may comprise an optical current sensor, preferably either a fibre optic cable coil or a crystal.

The electrical system may comprise a ground vehicle's electrical system. The output device may comprise a CPU of the ground vehicle or may comprise a display on a dashboard of the ground vehicle.

The invention also provides a method for diagnosing degradation of a plurality of wires in an electrical system having plurality of loads connected by the plurality of wires to a direct current power source, the plurality of wires arranged into a bundle near the power source. The method comprises placing a current sensor proximate to the bundle for producing a signal representative of a current in the bundle, monitoring a time-rate-of-change of the signal from the current sensor, comparing the time-rate-of-change of the signal from the current sensor to expected patterns of currents drawn by the plurality of loads and patterns of arcs which may occur in the plurality of wires, and, applying time domain reflectometry to produce an indication of a location at which an arc occurred in the plurality of wires.

The electrical system may comprise a ground vehicle's electrical system, and the method may further comprise providing the indication of the location at which the arc occurred to a CPU of the ground vehicle or may further comprise displaying the indication of the location at which the arc occurred on a dashboard of the ground vehicle.

The invention also provides a tool for diagnosing degradation of a plurality of wires in an electrical system having plurality of loads connected by the plurality of wires to a direct current power source, the plurality of wires arranged into a bundle near the power source. The tool comprises a current sensor located proximate to the bundle for producing a signal representative of a current in the bundle, a signal processor coupled to the sensor to receive the signal from the current sensor, a pattern database coupled to the signal processor to provide the signal processor with expected patterns of currents drawn by the plurality of loads and patterns of arcs which may occur in the plurality of wires, and, an output device coupled to the signal processor to receive an indication of a location at which an arc occurred in the plurality of wires.

### BRIEF DESCRIPTION OF DRAWINGS In drawings illustrating non-limiting embodiments of the invention:

FIG. 1 schematically depicts a prior art example of an electrical system;

FIG. 2 schematically depicts a diagnostic system according to a preferred embodiment of the invention, configured for monitoring the electrical system of FIG. 1; and,

FIG. 3 illustrates a method carried out by the diagnostic system of FIG. 2 in a preferred embodiment of the invention.

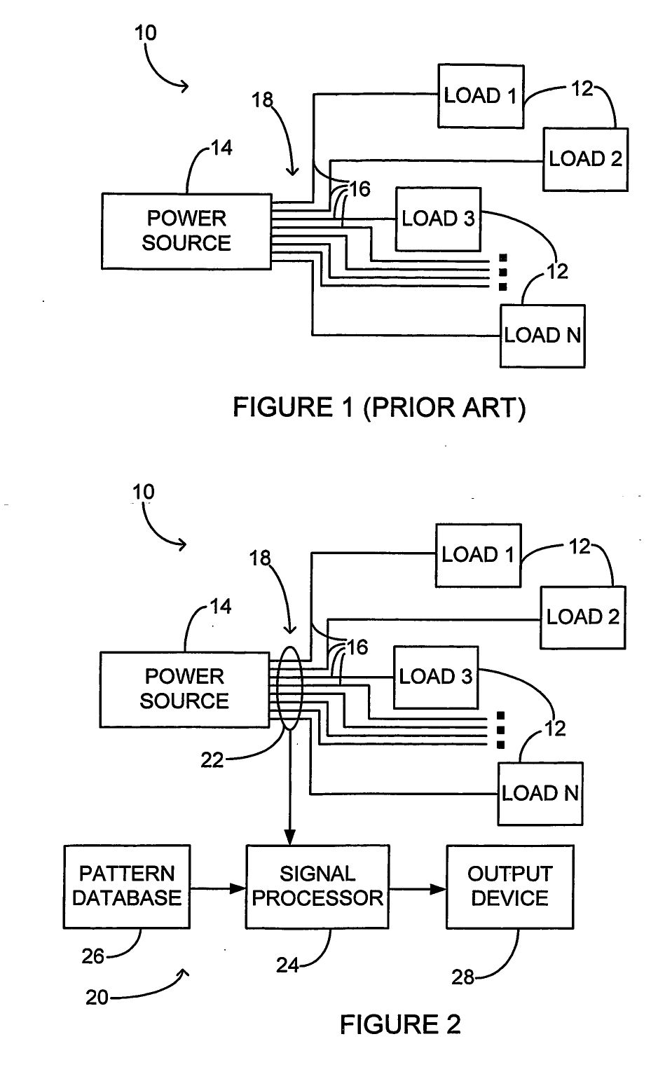

### DESCRIPTION

Throughout the following description specific details are set forth in order to provide a more thorough understanding of the invention. However, the invention may be practiced without these particulars. In other instances, well known elements have not been shown or described in detail to avoid unnecessarily obscuring the present invention. Accordingly, the specification and drawings are to be regarded in an illustrative, rather than a restrictive, sense.

FIG. 2 illustrates a diagnostic system 20 according to a preferred embodiment of the invention. Diagnostic system 20 is configured monitor wires 16 for arcing, which indicates degradation of wires 16. Diagnostic system 20 comprises a current sensor 22 which provides a signal to a signal processor 24. Signal processor 24 compares the signal to patterns stored in a pattern database 26 to determine when a dc arc occurs in one of wires 16 and calculate the location where the arc occurred. Signal processor 24 provides the location to an output device 28. It is to be understood that signal processor 24, pattern database 26, or output device 28, may be separate elements or they, or any two of them, may be combined into a single element.

Sensor 22 preferably comprises an optical current sensor, which may be fibre, slab or crystal, with a resolution of 5×10⁻⁶ amperes and a bandwidth of dc to 50 kHz. Optical sensors of this general type are typically manufactured by Sumitomo in Japan and others. Sensor 22 is wrapped around or clipped over bundle 18. The light within the fibre, slab or crystal is perturbed by the electromagnetic field produced by the current in bundle 18 and the sensor can be calibrated to measure the current in bundle 18 with sufficient accuracy and linearity.

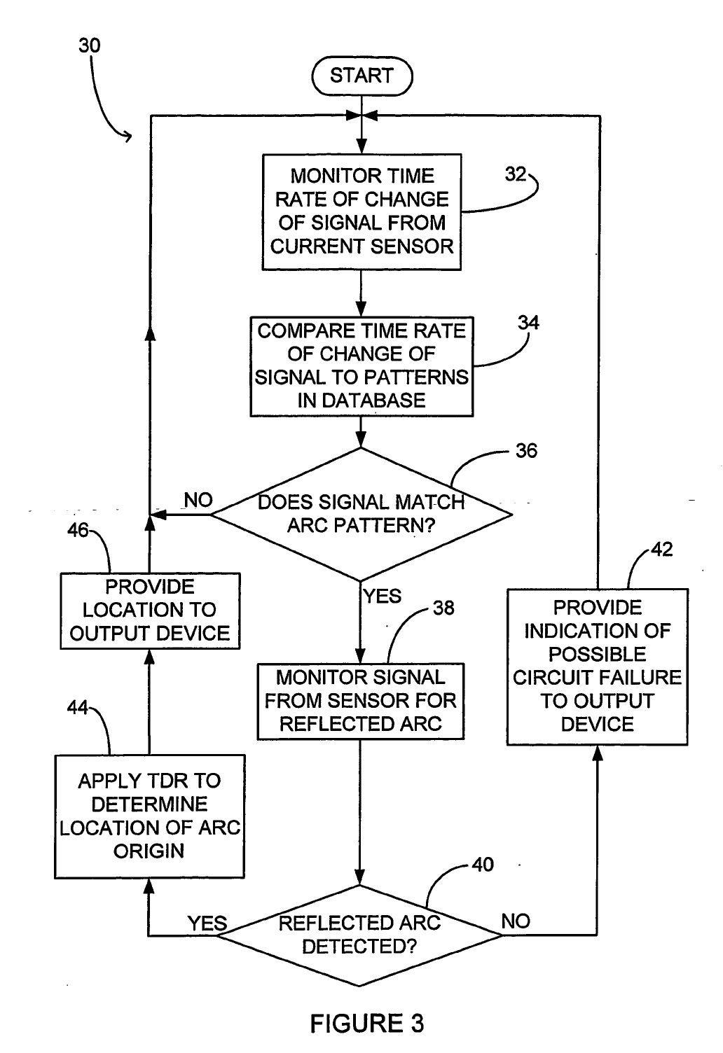

FIG. 3 illustrates a method 30 carried out by diagnostic system 20 in a preferred embodiment of the invention. At block 32, signal processor 24 monitors the time-rate-of-change of the signal from sensor 22. Each load 12, as it uses electrical power, will draw current through one of the wires 16. The time-rate-of-change of the current will create a pattern. Such patterns which are expected to be created by loads 12 are stored in pattern database 26. Also stored in database 26 are patterns expected to be created by arcs. An arc will produce a sharp spike in a graph of current versus time, due to the inductance and capacitance which are generally present when loads 12 draw current. The signal monitored by signal processor 24 may include a plurality of patterns superimposed upon each other. At block 34 signal processor 24 compares the signal to the patterns in database 26 and at block 36 it determines whether the signal includes an arc pattern.

The steps of blocks 32 to 36 are repeated until an arc is detected (“YES” output of block 36), at which point method 30 proceeds to block 38. At block 38, signal processor 24 monitors the signal from sensor 22 for a reflection caused by the arc propagating along the wire 16 upon which it occurred towards load 12 and then reflecting back toward sensor 22. If a reflection of the arc is not detected at block 40, the method proceeds to block 42, at which point signal processor 24 provides an indication of a possible failure in electrical system 10 to output device 28, then returns to block 32.

If a reflection of the arc is detected at block 40, method 30 proceeds to block 44 where signal processor determines the location at which the arc occurred. Signal processor 24 is supplied with information about the lengths of wires 16 during calibration of system 20. The location of the cable wiring fault or sparking may be calculated by signal processor 24 using a technique called time domain reflectometry or TDR. This method is disclosed in the following publication: Matthew S. Mashikian, “Partial Discharge Location as a Diagnostic Tool for Power Tools” 1999 IEEE/PES Transmission and Distribution Conference, New Orleans La., Apr. 11-16, 1999, Panel on Diagnostic Measurement Techniques for Power Cables. (See in particular FIG. 3 of Mashikian). At block 46 signal processor 24 provides the location at which the arc occurred to output device 28, and then method 3 returns to block 32.

Output device 28 may comprise a CPU of a vehicle's electronic system, a display on the dashboard of a car or truck, or any suitable device. In some embodiments output device 28 may be part of a diagnostic tool incorporating diagnostic system 20.

As will be apparent to those skilled in the art in the light of the foregoing disclosure, many alterations and modifications are possible in the practice of this invention without departing from the scope thereof. For example, although the above description contemplates use of a diagnostic systems according to a preferred embodiment of the invention to monitor a vehicle's electrical system, diagnostic systems and methods within the scope of the invention could be used to monitor an electrical system with a dc power source. Accordingly, the scope of the invention is to be construed in accordance with the substance defined by the following claims.

What is claimed is:

1. A system for diagnosing degradation of a plurality of wires in an electrical system having plurality of loads connected by the plurality of wires to a direct current power source, the plurality of wires arranged into a bundle near the power source, the system comprising:
(a) a current sensor located proximate to the bundle for producing a signal representative of a current in the bundle;
(b) a signal processor coupled to the sensor to receive the signal from the current sensor;
(c) a pattern database coupled to the signal processor to provide the signal processor with expected patterns of currents drawn by the plurality of loads and patterns of arcs which may occur in the plurality of wires; and,
(d) an output device coupled to the signal processor to receive an indication of a location at which an arc occurred in the plurality of wires.

2. The system of claim 1 wherein the current sensor comprises an optical current sensor.

3. The system of claim 1 or 2 wherein the electrical system comprises a mobile vehicle's electrical system.

4. The system of claim 3 wherein the output device comprises a CPU of the mobile vehicle.

5. The system of claim 3 wherein the output device comprises a display on a dashboard of the mobile vehicle.

6. A method for diagnosing degradation of a plurality of wires in an electrical system having plurality of loads connected by the plurality of wires to a direct current power source, the plurality of wires arranged into a bundle near the power source, the method comprising:
(a) placing a current sensor proximate to the bundle for producing a signal representative of a current in the bundle;
(b) monitoring a time-rate-of-change of the signal from the current sensor;
(c) comparing the time-rate-of-change of the signal from the current sensor to expected patterns of currents drawn by the plurality of loads and patterns of arcs which may occur in the plurality of wires; and,
(d) applying time domain reflectometry to produce an indication of a location at which an arc occurred in the plurality of wires.

7. The method of claim 6 wherein the electrical system comprises a mobile vehicle's electrical system, the method further comprising providing the indication of the location at which the arc occurred to a CPU of the mobile vehicle.

8. The method of claim 6 wherein the electrical system comprises a mobile vehicle's electrical system, the method further comprising displaying the indication of the location at which the arc occurred on a dashboard of the mobile vehicle.

9. A tool for diagnosing degradation of a plurality of wires in an electrical system having plurality of loads connected by the plurality of wires to a direct current power source, the plurality of wires arranged into a bundle near the power source, the tool comprising:
(a) a current sensor located proximate to the bundle for producing a signal representative of a current in the bundle;
(b) a signal processor coupled to the sensor to receive the signal from the current sensor;
(c) a pattern database coupled to the signal processor to provide the signal processor with expected patterns of currents drawn by the plurality of loads and patterns of arcs which may occur in the plurality of wires; and,
(d) an output device coupled to the signal processor to receive an indication of a location at which an arc occurred in the plurality of wires.
